(19) United States
(12) Patent Application Publication
(10) Pub. No.: US 2014/0073087 A1
(43) Pub. Date: Mar. 13, 2014

(54) METHOD OF FABRICATING A SEMICONDUCTOR PACKAGE

(71) Applicants: Pin-Cheng Huang, Taichung Hsien (TW); Yi-Che Lai, Taichung Hsien (TW)

(72) Inventors: Pin-Cheng Huang, Taichung Hsien (TW); Yi-Che Lai, Taichung Hsien (TW)

(21) Appl. No.: 13/680,728

(22) Filed: Nov. 19, 2012

(30) Foreign Application Priority Data
Sep. 10, 2012 (TW) 101132954

(51) Int. Cl. H01L 21/56

(52) U.S. Cl. CPC H01L 21/56
USPC 438/107

(57) ABSTRACT

A method of fabricating a semiconductor package is provided, including: providing a substrate having opposite first and second surfaces and a plurality of conductive through holes penetrating the first and second surfaces, disposing the substrate on a first carrier through the second surface thereof, and keeping the first carrier flat and free of warpage; attaching at least a first semiconductor chip to the first surface of the substrate and electrically connecting the first semiconductor chip and the substrate; removing the first carrier; and attaching the substrate to a packaging substrate through the second surface thereof and electrically connecting the substrate and the packaging substrate, thereby preventing the semiconductor package from warpage, increasing product yield, reducing fabrication cost, and improving thermal dissipation.

### BACKGROUND OF THE INVENTION

1. Field of the Invention

The present invention relates to methods of fabricating semiconductor packages, and, more particularly, to a method of fabricating a semiconductor package having an interposer.

2. Description of Related Art

To meet the trend of miniaturization, multi-function, high electrical performance and high operational speed of electronic products, nowadays semiconductor packaging industry follows this trend to develop packages with the characteristics of miniaturization, superior electrical performance, multi-function, and high speed.

Flip-chip technology can be applied to reducing chip packaging sizes and shortening signal transmission paths and therefore has become widely used in semiconductor chip packaging. Various packages types, such as chip scale packages (CSPs), direct chip attached (DCA) packages and multi-chip module (MCM) packages, have been achieved by the flip-chip method.

Further, TSI (through silicon interposer) technology is developed for attaching a semiconductor chip to a silicon interposer to integrate several modules of various chips with different functions in a package. Such a package generally has a carrier, a TSI, at least a semiconductor chip and an encapsulant encapsulating the carrier, the TSI, and the semiconductor chip. The TSI and the semiconductor chip are electrically connected by a plurality of solder bumps (μ-bumps), and the silicon interposer and the carrier are electrically connected by a plurality of C4 bumps.

The TSI has a plurality of through silicon vias (TSV) penetrating therethrough. Since the TSI and the semiconductor chip are made of similar materials, problems caused by thermal expansion mismatch can be prevented. Generally, a plurality of TSVs are formed in a silicon wafer first, and then a redistribution layer, if needed, is formed on an upper side of the wafer and a plurality of solder bumps (μ-bumps) are formed on the redistribution layer for electrically connecting semiconductor chips. After the semiconductor chips are electrically connected to the redistribution layer, a molding process is performed such that an encapsulant made of a molding compound is formed to encapsulate the semiconductor chips to thereby protect the semiconductor chips against external environment effects. Subsequently, a thinning process by grinding is performed to the lower side of the wafer to expose the TSVs. Thereafter, if needed, a redistribution layer is formed on the TSVs and a plurality of solder bumps are disposed on the redistribution layer. Subsequently, a singulation process is performed to form a plurality of TSI modules having semiconductor chips. Then, the TSI modules can be electrically connected to packaging substrates. However, as such a TSI module is integrated with more semiconductor chips and its TSI becomes thinner, the ratio of metal to silicon in the TSI increases, thereby easily causing warpage and adversely affecting the product yield of the overall package.

Although the above-described package has a reduced thickness compared with the conventional packages, the fabrication process of the package is time-consuming Further, when the silicon wafer is thinned, the TSVs of the silicon wafer can be easily damaged. The damaged TSVs cannot be easily tested since the fabrication of the TSVs is not actually finished until conductive bumps are formed on the lower side of the silicon wafer. Furthermore, the silicon wafer is easy to warp during the fabrication process, thus reducing product yield and increasing fabrication cost. Moreover, the molding compound adversely affects thermal dissipation of the package.

Therefore, there is an urgent need to provide a method of fabricating a semiconductor package to overcome the above-described disadvantages.

### SUMMARY OF THE INVENTION

In view of the above-described disadvantages, the present invention provides a method of fabricating a semiconductor package, comprising: providing a substrate having opposite first and second surfaces and a plurality of conductive through holes penetrating the first and second surfaces, disposing the substrate on a first carrier through the second surface thereof, and keeping the first carrier flat and free of warpage; attaching at least a first semiconductor chip to the first surface of the substrate and electrically connecting the first semiconductor chip and the substrate; removing the first carrier; and attaching the substrate to a packaging substrate through the second surface thereof and electrically connecting the substrate and the packaging substrate.

Therefore, by keeping the first carrier flat and free of warpage, the present invention prevents warpage of the overall structure. Compared with the prior art, the present invention makes it possible for a testing process to be performed earlier to determine the electrical contact quality of the substrate, thereby increasing product yield and reducing fabrication cost. Further, instead of the conventional molding, the present invention forms an underfill between the first semiconductor chip and the first surface of the substrate to reduce fabrication cost and facilitate a multi-layer stack packaging of a plurality of semiconductor chips. Furthermore, since most surfaces of the semiconductor chips are exposed without the underfill covering, thus thermal dissipation effect is improved.

In addition, metal, dielectrics, and their associated geometric distributions in the substrate can be optimized or adjusted to match the upper first semiconductor chip and the lower packaging substrate in effective coefficient of thermal expansion (CTE), thereby alleviating warpage of the semiconductor package, increasing product yield, improving thermal dissipation and increasing product reliability.

### BRIEF DESCRIPTION OF DRAWINGS

FIGS. 1A to 1F-4 are cross-sectional views illustrating a semiconductor package and a method of fabricating the semiconductor package according to the present invention, wherein FIGS. 1A′ and 1A″ show different embodiments of FIG. 1A, and FIGS. 1F-2 to 1F-4 show different embodiments of FIG. 1F-1.

### DETAILED DESCRIPTION OF PREFERRED EMBODIMENTS

The following embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms, such as “upper”, “lower”, “warpage-free”, “flat”, “attach”, “a” etc., are merely for illustrative purpose and should not be construed to limit the scope of the present invention.

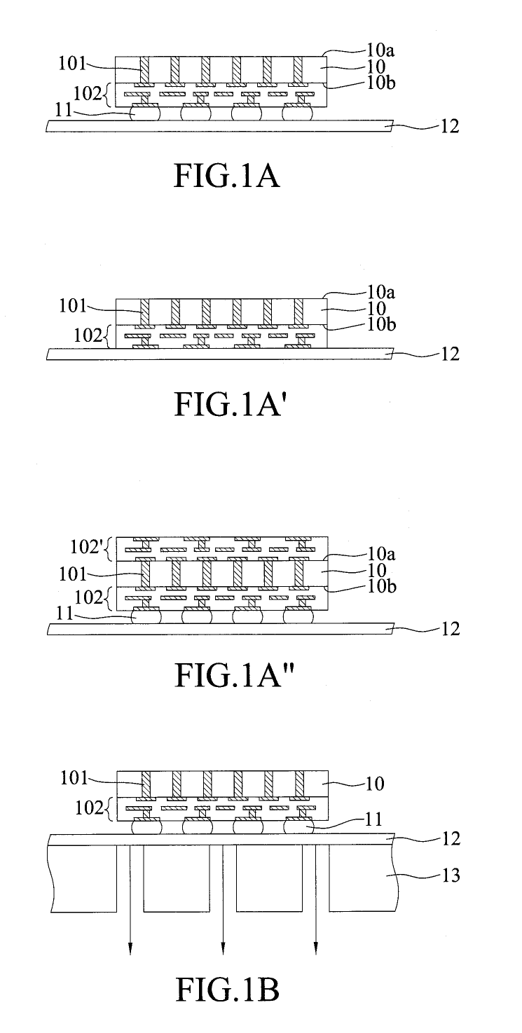

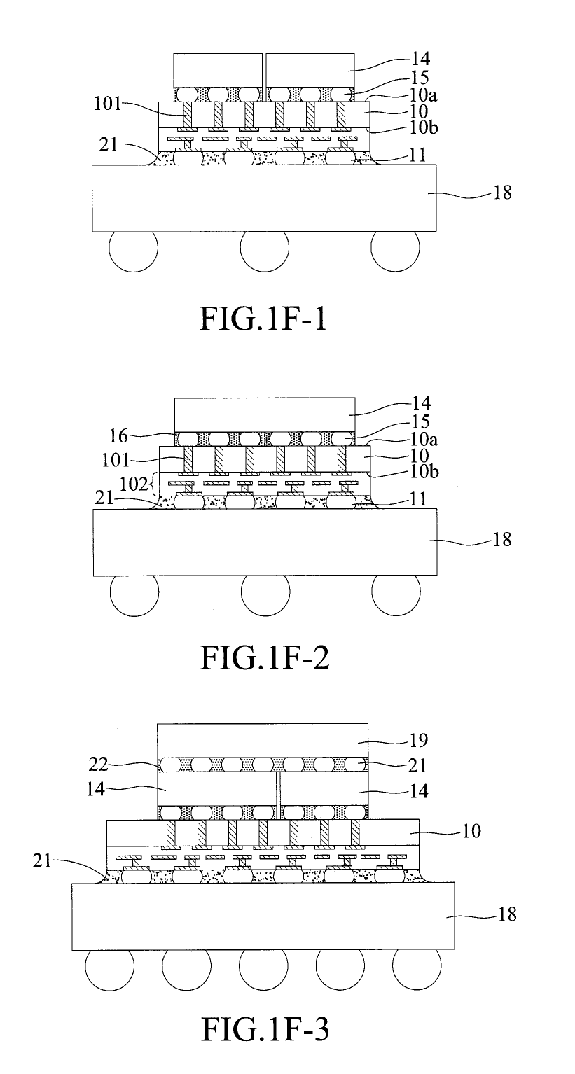

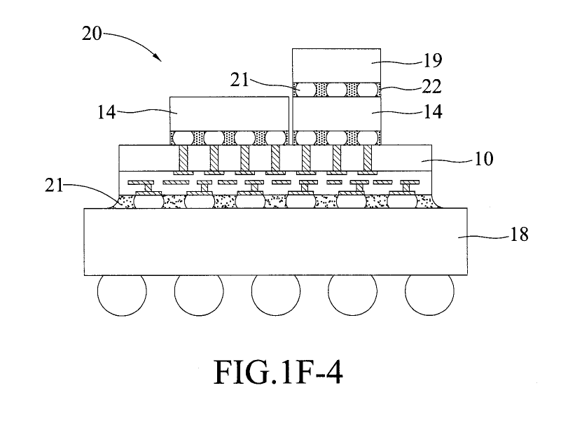

FIGS. 1A to 1F-4 are cross-sectional views illustrating a semiconductor package and a method of fabricating the semiconductor package according to the present invention. FIGS. 1A′ and 1A″ show different embodiments of FIG. 1A, and FIGS. 1F-2, 1F-3 and 1F-4 show different embodiments of FIG. 1F-1.

Referring to FIG. 1A, a substrate 10 is provided. The substrate 10 has opposite first and second surfaces 10a, 10b and a plurality of conductive through holes 101 penetrating the first and second surfaces 10a, 10b. A redistribution layer 102 is optionally formed on the second surface 10b of the substrate 10 and electrically connected to the conductive through holes 101, and a plurality of conductive bumps 11 such as C4 bumps are formed on the redistribution layer 102. The substrate 10 is disposed on a first carrier 12 through the conductive bumps 11. Further, a redistribution layer (not shown) can be optionally formed on the first surface 10a of the substrate 10 and electrically connected to the conductive through holes 101. In an embodiment, the substrate 10 is a through silicon interposer, and the conductive through holes 101 are made of silicon. In other embodiments, the substrate 10 is made of Si, GaAs, SiC, glass, semiconductor-on-insulator (SOI), or the combination thereof. For example, the substrate 10 is a through glass interposer, and the conductive through holes 101 are made of glass. The substrate 10 has a height between 20 and 180 um. The first carrier 12 is made of a UV release tape. The dielectric materials of the redistribution layer 102 is different from that of the substrate 10.

In another embodiment, referring to FIG. 1A′, the substrate 10 is directly disposed on the first carrier 12 instead of through the conductive bumps 11.

In another embodiment, referring to FIG. 1A″, a redistribution layer 102′ is formed on the first surface 10a of the substrate 10 and electrically connected to the conductive through holes 101, and a redistribution layer 102 is formed on the second surface 10b of the substrate 10 and electrically connected to the conductive through holes 101.

Referring to FIG. 1B, following after FIG. 1A, the first carrier 12 is disposed on a carriage 13 by air suction such that the first carrier 12 is kept flat and free of warpage. In another embodiment, the first carrier 12 can be disposed on the carriage 12 by electrostatic force.

Referring to FIG. 1C, at least a first semiconductor chip 14 is attached to the first surface 10a of the substrate 10 in a manner that a plurality of conductive bumps 15 such as u-bumps are formed between the first semiconductor chip 14 and the substrate 10 for electrically connecting the first semiconductor chip 14 and the conductive through holes 101. In an embodiment, the first semiconductor chip 14 is a memory chip, an RF chip, a logic chip, an analog chip or a chip comprising passive electronic devices.

Referring to FIG. 1D, an underfill 16 is formed between the first semiconductor chip 14 and the first surface 10a of the substrate 10. The underfill 16 can contain an epoxy resin mixed with a filler (not shown) for changing the viscosity, CTE and hardness of the underfill. The filler can be SiO₂ or Al₂O₃ particles.

Referring to FIG. 1E, the first carrier 12 is removed and the first semiconductor chip 14 is disposed on a second carrier 17 opposite to the first surface 10a of the substrate 10, and a testing process is performed to the conductive bumps 11. The second carrier 17 can be a UV release tape.

Referring to FIG. 1F-1, the second carrier 17 is removed, and the substrate 10 is attached to a packaging substrate 18 with the conductive bumps 11 formed therebetween for electrically connecting the packaging substrate 18 and the conductive through holes 101 of the substrate 10. Then, an underfill 21 is formed between the second surface 10b of the substrate 10 and the packaging substrate 18. Further, a singulation process can be performed according to the practical need.

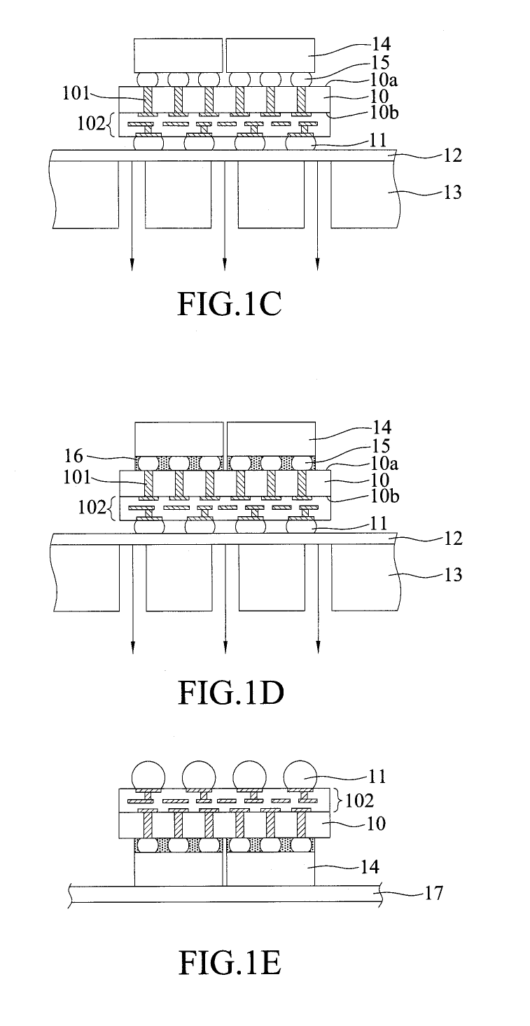

FIGS. 1F-2, 1F-3 and 1F-4 show different embodiments of FIG. 1F-1. In FIG. 1F-2, only one semiconductor chip 14 is disposed on the substrate 10. In FIG. 1F-3, at least a second semiconductor chip 19 is attached to the first semiconductor chips 14 and a plurality of conductive bumps 23 such as solder bumps are formed between the first semiconductor chips 14 and the second semiconductor chip 19 for electrically connecting the first semiconductor chips 14 and the second semiconductor chip 19. An underfill 22 is further formed between the first semiconductor chips 14 and the second semiconductor chip 19. In FIG. 1F-4, at least a second semiconductor chip 19 is attached to one of the first semiconductor chips 14 and a plurality of conductive bumps 23 are formed between the first semiconductor chip 14 and the second semiconductor chip 19 for electrically connecting the first semiconductor chip 14 and the second semiconductor chip 19. An underfill 22 is further formed between the first semiconductor chip 14 and the second semiconductor chip 19. The second semiconductor chip 19 can be a memory chip, an RF chip, a logic chip, an analog chip or a chip comprising passive electronic devices.

In FIG. 1F-4, since a gap 20 is formed between the first semiconductor chips 14 and the second semiconductor chip 19, a UV release adhesive (not shown) can be formed on the second carrier 17 before the first semiconductor chips 14 are disposed on the second carrier 17. As such, when the first semiconductor chips 14 are disposed on the second carrier 17, the gap 20 can be filled by the UV release adhesive so as to increase the stability. When the second carrier 17 is removed, the UV release adhesive can be removed together with the second carrier 17.

The present invention further provides a semiconductor package, which has: a packaging substrate 18; a substrate 10 having opposite first and second surfaces 10a, 10b and a plurality of conductive through holes 101 penetrating the first and second surfaces 10a, 10b, the substrate 10 being attached to the packaging substrate 18 through the second surface 10b thereof; at least a semiconductor chip 14 disposed on the first surface 10a of the substrate 10 and electrically connected to the substrate 10; and an underfill 16 formed between the first semiconductor chip 14 and the first surface 10a of the substrate 10.

The above-described package can further have an underfill 21 formed between the packaging substrate 18 and the second surface 10b of the substrate 10. At least a semiconductor chip 19 can further be disposed on the first semiconductor chip 14 and an underfill 22 can further be formed between the first semiconductor chip 14 and the second semiconductor chip 19.

The substrate 10 can be a through silicon interposer, and the conductive through holes 101 can be made of silicon.

In an embodiment, a plurality of conductive bumps 15 are formed between the first semiconductor chip 14 and the first surface 10a of the substrate 10 for electrically connecting the first semiconductor chip 14 and the conductive through holes 101. Further, a plurality of conductive bumps 11 are formed between the packaging substrate 18 and the second surface 10b of the substrate 10 for electrically connecting the packaging substrate 18 and the conductive through holes 101.

A plurality of conductive bumps 23 can further be formed between the first semiconductor chip 14 and the second semiconductor chip 19 for electrically connecting the first semiconductor chip 14 and the second semiconductor chip 19.

If needed, a redistribution layer 102 can be formed on the second surface 10b of the substrate 10 and electrically connected to the conductive through holes 101. Furthermore, the redistribution layer 102 is attached to a package substrate 18 opposite to the first surface 10a of the substrate 10.

Therefore, by keeping the first carrier flat and free of warpage, the present invention prevents warpage of the overall structure. Compared with the prior art, the present invention makes it possible for a testing process to be performed earlier to determine the electrical contact quality of the substrate, thereby increasing product yield and reducing fabrication cost. Further, instead of the conventional molding compound, the present invention forms an underfill between the first semiconductor chip and the first surface of the substrate to reduce fabrication cost and facilitate a multi-layer stack packaging made up of a plurality of semiconductor chips by forming an underfill and conductive bumps. Furthermore, since most surfaces of the semiconductor chips are exposed without the underfill covering, thus thermal dissipation is improved.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method of fabricating a semiconductor package, comprising:
providing a substrate having opposite first and second surfaces and a plurality of conductive through holes penetrating the first and second surfaces, disposing the substrate on a first carrier through the second surface thereof, and keeping the first carrier flat and free of warpage;
attaching at least a first semiconductor chip to the first surface of the substrate and electrically connecting the first semiconductor chip and the substrate;
removing the first carrier; and
attaching the substrate to a packaging substrate through the second surface thereof and electrically connecting the substrate and the packaging substrate.

2. The method of claim 1, wherein the first semiconductor chip is attached to the first surface of the substrate in a manner that a plurality of conductive bumps are formed between the first surface of the substrate and the first semiconductor chip for electrically connecting the first semiconductor chip and the substrate.

3. The method of claim 1, further comprising forming an underfill between the first semiconductor chip and the first surface of the substrate.

4. The method of claim 1, wherein the substrate is attached to the packaging substrate in a manner that a plurality of conductive bumps are formed between the packaging substrate and the second surface of the substrate for electrical connecting the packaging substrate and the substrate.

5. The method of claim 1, further comprising forming an underfill between the second surface of the substrate and the packaging substrate.

6. The method of claim 1, after removing the first carrier, further comprising disposing the first semiconductor chip on a second carrier opposite to the first surface of the substrate, performing a testing process, and then removing the second carrier.

7. The method of claim 6, further comprising forming a UV release adhesive on the second carrier before disposing the first semiconductor chip on the second carrier, wherein the step of removing the second carrier further comprises removing the UV release adhesive simultaneously, and the second carrier is a UV release tape.

8. The method of claim 1, wherein the first carrier is disposed on a carriage by air suction or electrostatic force to be kept flat and free of warpage.

9. The method of claim 1, further comprising electrically connecting at least a second semiconductor chip to the first semiconductor chip.

10. The method of claim 1, wherein the first carrier is a UV release tape.

11. The method of claim 1, wherein the substrate is a through silicon interposer, and the conductive through holes are made of silicon.

12. The method of claim 1, wherein the substrate further has a redistribution layer formed on the first surface or the second surface thereof and electrically connected to the conductive through holes.

13. The method of claim 12, wherein a dielectric material the redistribution layer is different from that of the substrate.

14. The method of claim 1, wherein the substrate is a through glass interposer and the conductive through holes are made of glass.
